(19) United States
(12) Patent Application Publication
(10) Pub. No.: US 2026/0082539 A1
(43) Pub. Date: Mar. 19, 2026

(54) SYSTEM AND METHODS FOR VERTICAL ELECTRODE SUPPORTS

(71) Applicant: Samsung Electronics Co., Ltd., Suwon-si (KR)

(72) Inventor: Wangee KIM, Dublin, CA (US)

(21) Appl. No.: 19/206,034

(22) Filed: May 12, 2025

Related U.S. Application Data
(60) Provisional application No. 63/696,375, filed on Sep. 18, 2024.

(51) Int. Cl. H10B 12/00

(52) U.S. Cl. CPC H10B 12/30; H10B 12/02

(57) ABSTRACT

Disclosed herein are methods, devices and systems including a substrate with a planar surface, a first electrode extending in a first direction orthogonal to the planar surface of the substrate, a second electrode extending in a second direction parallel to the planar surface of the substrate, the second electrode contacting the first electrode, a third electrode extending in the second direction, a first dielectric material between the first electrode and the third electrode, the first dielectric material contacting the first electrode, a second dielectric material between the first electrode and the second electrode, with the first dielectric material between the first electrode and the second dielectric material.

### CROSS-REFERENCE TO RELATED APPLICATION

This application claims the priority benefit under 35 U.S.C. § 119(e) of U.S. Provisional Patent Application Ser. No. 63/696,375 filed on Sep. 18, 2024, the disclosure of which is incorporated herein by reference in its entirety.

### TECHNICAL FIELD

The subject matter disclosed herein relates to microelectronics and integrated circuits (IC) structures. More particularly, the subject matter disclosed herein relates to a semiconductor structure involving an electrode having a three-dimensional shape and the supporting mechanism.

### BACKGROUND

Semiconductor devices may be created using complex three-dimensional structures made up of sets of smaller components. Such components may include circuit components, such as transistors, capacitors, etc., reproduced in large numbers and addressed using a matrix of intersecting lines. However, forming an address matrix can be complex and may face difficulties in forming conductive lines and/or ensuring sufficient isolation between individual lines. It is further noted that background concepts discussed herein are for informational purposes only and are not intended to limit the present disclosure, nor should the background or field described be intended to limit the disclosure herein to a particular use or concept.

### SUMMARY

An example embodiment provides a device with a substrate with a planar surface, a first electrode extending in a first direction orthogonal to the planar surface of the substrate, a second electrode extending in a second direction parallel to the planar surface of the substrate, the second electrode contacting the first electrode, a third electrode extending in the second direction, a first dielectric material between the first electrode and the third electrode, the first dielectric material contacting the first electrode, a second dielectric material between the first electrode and the second electrode, with the first dielectric material between the first electrode and the second dielectric material. The first dielectric material may include at least one of a carbide, nitride or oxide. The second dielectric material may include at least one of a carbide, nitride or oxide. The first dielectric material may differ from the second dielectric material. The first electrode may extend from a contact on a surface of the device to the second electrode, and the third electrode may be electrically isolated from the first electrode. The first dielectric material may extend in the first direction and the second dielectric material may extend in the second direction. A fourth electrode may extend in the first direction and contact the third electrode, the fourth electrode may be electrically isolated from the first electrode. The second electrode may be a word line.

An example embodiment provides a system including a substrate having a planar surface, a first electrode extending in a first direction orthogonal to the planar surface of the substrate, the first electrode extending from a first contact to a second electrode, the second electrode extending in a second direction parallel to the planar surface of the substrate. A third electrode may extend in the first direction, with the third electrode extending in the first direction from a second contact to a fourth electrode, and the fourth electrode extending in the second direction. A first dielectric material may be between the first electrode and the third electrode, while a second dielectric material may be between the second electrode and the fourth electrode, and the second dielectric material may be between the first dielectric material and the first electrode. The first dielectric material may include at least one of a carbide, nitride or oxide. The second dielectric material may include at least one of a carbide, nitride or oxide. The first dielectric material may extend in the first direction. The first electrode may be electrically isolated from the fourth electrode. The material of the first dielectric material may be different from the material of the second dielectric material. The second dielectric material may extend in the second direction beyond the fourth electrode.

An example embodiment provides a method including forming a dielectric pillar on a substrate, the substrate having a planar surface; forming a first trench within the dielectric pillar; forming a dielectric cap within the first trench, the dielectric cap aligned with a first electrode, the first electrode extending in a first direction parallel to the planar surface of the substrate; forming an upper dielectric material over the dielectric cap; removing at least a portion of the upper dielectric material to form a second trench; and forming a conductor within the second trench, the conductor forming a second electrode which extends in a second direction orthogonal to the planar surface of the substrate, and the dielectric pillar and the upper dielectric material are formed of a first dielectric material while the dielectric cap is formed of a second dielectric material different from the first dielectric material. The conductor may be formed by at least one of chemical vapor deposition, physical vapor deposition, or atomic layer deposition. The first dielectric material may include an oxide, and the second dielectric material may include a nitride. The first dielectric material may be formed by at least one of atomic layer deposition and chemical vapor deposition. The second dielectric material may act as an etch stop during formation of the second trench. Prior to forming the dielectric cap within the first trench, a staircase formation may be formed, including a first trench at a first depth and a second trench at a second depth greater than the first trench. The dielectric cap may be between the second electrode and the dielectric pillar.

### BRIEF DESCRIPTION OF THE DRAWING

In the following section, the aspects of the subject matter disclosed herein will be described with reference to example embodiments illustrated in the figures, in which:

FIG. 1A depicts a cross-sectional view of a semiconductor structure according to various embodiments of the subject matter disclosed herein;

FIG. 1B depicts an enlarged perspective view of a semiconductor structure according to various embodiments of the subject matter disclosed herein;

FIG. 2 depicts a cross-sectional view of an example embodiment of a semiconductor structure at different stages of its manufacture;

FIGS. 3A-3M depict cross-sectional views of an example embodiment of a semiconductor structure at different stages of its manufacture;

FIG. 4 depicts a plan view of a method forming a semiconductor structure according to various embodiments of the subject matter disclosed

FIG. 5A-5C depict perspective views of an example embodiment of a semiconductor structure at different stages of its manufacture.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination.

As used herein, memory may refer to various forms of semiconductor memory, including both volatile memory where data is lost when power is turned off, and non-volatile memory, which may retain data after power is turned off. Examples of volatile memory may include forms of random-access memory such as static random-access memory (SRAM), dynamic random-access memory (DRAM), synchronous dynamic random-access memory (SDRAM), double data rate DRAM or DDR DRAM. Examples of non-volatile memory may include flash memory devices, read only memory (ROM), programmable read only memory (PROM), electronically programmable read only memory (EPROM), electronically erasable and programmable read only memory (EEPROM), phase-change random-access memory (Phase-change RAM), ferroelectric random-access memory (FRAM), and resistive random-access memory (RRAM).

As used herein, three-dimensional memory or 3D memory may refer to any form of memory, including both volatile and non-volatile memory, containing individual elements organized in three-dimensions. For example, multiple planes of memory cells may be stacked upon each other. As used herein, vertically stacked dynamic random-access memory (VSDRAM) may refer to a three-dimensional structure of DRAM, where individual layers of DRAM elements may be stacked upon each other. In some embodiments, 3D memory may be organized that the addressing matrix is orthogonal to the memory cells. That is, in some embodiment, each of the bit line, the word line, and capacitors may extend in a different direction, such that each direction is orthogonal to the other. In some embodiments, the vertical direction, that is the direction orthogonal to the plane of the substrate, may be parallel to the bit line. In some embodiments, the word line or the capacitors may extend in the vertical direction. As used herein, bit line, word line, read line, address line, grid, array, and matrix may be used interchangeably to describe the various electrodes organized to provide a signal where two lines intersect within a larger device.

As used herein, conductors or conductive materials may refer to a variety of conductive materials, including which materials may be used alone or in combination with other materials. In some embodiments, the conductor includes a semiconductor material, such as silicon (Si), germanium (Ge), gallium arsenide (GaAs), indium phosphide (InP) or any other suitable material. In some embodiments, the conductor may include a metal such as copper (Cu), tungsten (W), titanium (Ti), either alone or in combination. In some embodiments, the conductor may include a combination of materials, including oxides and nitrides. Such a listing of elements is not intended to be exhaustive, and in other embodiments, any known other type of conductive material may be used.

As used herein, dielectrics or dielectric materials may refer to non-conductive materials, and may include materials such as various semiconductor materials as well as various semiconductor carbides, semiconductor nitrides, and/or semiconductor oxides, such as silicon nitride (Si₃N₄), silicon dioxide (SiO₂), etc. Such dielectric materials may have a relatively low relative permittivity (εᵣ), such as less than 10 (εᵣ<10), or less than 20 (εᵣ<20), or less than 30 (εᵣ<30), or less than 40 (εᵣ<40), or less than 50 (εᵣ<50), or less than 100 (εᵣ<100), and thus be a poor conductor. In some embodiments, a dielectric material may include a fluidic material. In some embodiments, a dielectric material may take the form of an air gap.

Disclosed herein are various embodiments of devices, systems and methods related to vertical electrodes within a 3D memory device having a cap and pillar supporter. In a memory device, one or more vertical electrodes may extend from a surface pad to a corresponding horizontal electrode. The one or more vertical electrodes may be used, in some embodiments, as part of the word line, while in other embodiments, the one or more vertical electrodes may be used as part of a bit line, source, drain, or bias. The one or more vertical electrodes may be formed within a contact pad area. The one or more horizontal electrodes may couple an electrical signal from the one or more vertical electrodes to one or more memory cells within a cell array. The one or more vertical electrodes may be each supported by a dielectric supporter, the dielectric supporter including a dielectric cap supported by a dielectric pillar. The dielectric supporter may have the dielectric pillar and the dielectric cap aligned with each other, and the dielectric pillar and dielectric cap may be both aligned with the one or more vertical electrodes. The alignment of the supporter and the one or more vertical electrodes allows the contact pads for the memory device to be tightly packed, allowing the overall size of the device to be reduced, as well as increasing the efficiency of the device by decreasing the distance between contacts and cell elements.

The dielectric pillar may be formed of a first dielectric material, while the dielectric cap may be formed of a second dielectric material. The one or more vertical electrodes may extend from a contact pad on the surface to the dielectric cap, where the top surface of the dielectric cap may be aligned to a first horizontal electrode. The bottom surface of the dielectric cap and top surface of the dielectric pillar may be aligned to a second horizontal electrode below the first horizontal electrode. The dielectric cap may thus provide physical support for the vertical electrode and electrical isolation between the first horizontal electrode and the second horizontal electrode, while the dielectric pillar may provide physical support for the cap, and electrical isolation from additional horizontal layers. The one or more vertical electrodes and the one or more horizontal electrodes may be formed in a staircase formation, where each pair of vertical and horizontal electrodes are coupled spaced apart both vertically and horizontally to provide both isolation between pairs of electrodes, and to provide a dense contact structure to minimize the size of the contact area. As such, the memory device may have a compact size with the alignment between the vertical electrodes and the supporter reducing the pad area, and reducing the distance between the contacts and the memory cells, thus increasing the efficiency and performance of the memory device.

Also disclosed herein are methods of forming the memory device. An epitaxial semiconductor structure is created having a first epitaxial semiconductor and a second epitaxial semiconductor formed over a base epitaxial layer on a substrate. The first epitaxial semiconductor and the second epitaxial semiconductor may form alternating layers within the epitaxial structure. An initial dielectric pillar may be formed of a first dielectric material and extend vertically through the epitaxial structure. The epitaxial structure may be treated to remove the base epitaxial layer and the second epitaxial semiconductor via a series of etching steps, with the remaining portions of the first epitaxial semiconductor being trimmed to form a series of recesses. Additional amounts of the first dielectric material may be formed to occupy the series of recesses and form a spacer dielectric. The initial dielectric pillar may have a partial removal process to form trenches within the first dielectric material. In some cases, an additional removal process may be used to form a staircase structure, with the depth of the etch increasing along with the horizontal distance. Upon the staircase structure, a second dielectric material may be formed, with the trenches filled with the second dielectric material. Excess portions of the second dielectric material may be removed via an etch process to form the dielectric cap. Additional first dielectric material may be formed to create a dielectric filler to refill those locations where the staircase structure was formed. The remaining first epitaxial semiconductor may be replaced by a first conducive material to form the one or more horizontal electrodes. Within the dielectric filler, dielectric trenches may be now formed to reach the one or more horizontal electrodes. In some embodiments, a selective etch process may be used to form the dielectric trenches, the selective etch process able to etch the first dielectric material, but unable to etch the second dielectric material, with the dielectric caps acting as an etch stop. A second conductive material may be formed within the dielectric trenches to create the one or more vertical electrodes. Thus, dielectric supporters may be directly aligned with the one or more vertical electrodes, with the dielectric cap further aligning the one or more vertical electrodes and the one or more horizontal electrodes. As a result of the alignment, the pad area may be reduced, providing a denser memory device with shorter distances for signals to travel, and creating a more efficient more device.

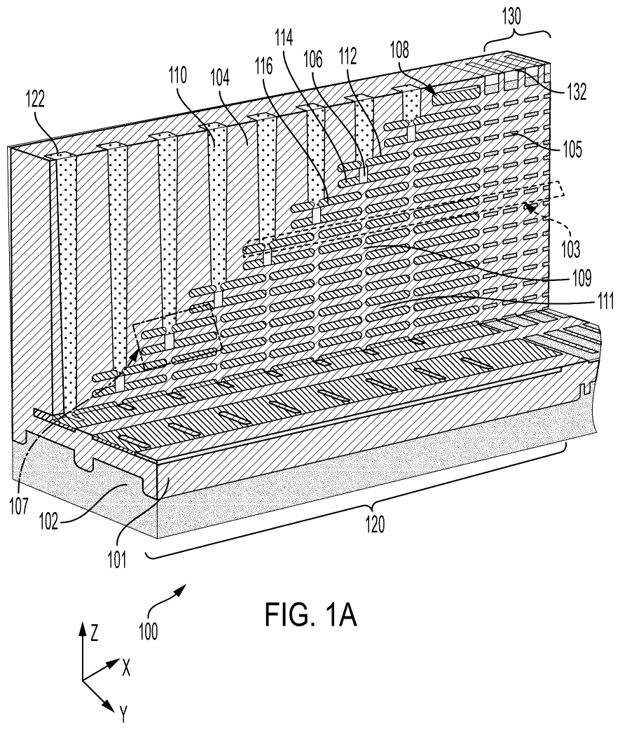

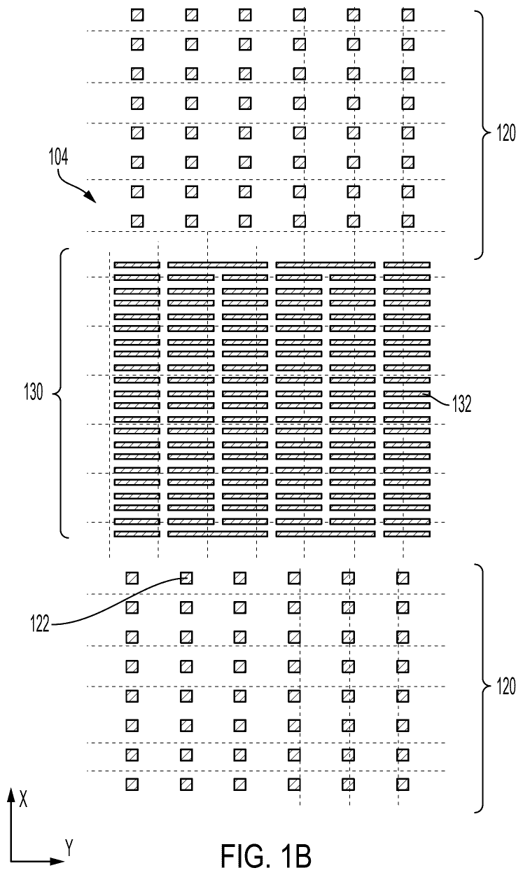

FIG. 1A depicts a cross-sectional perspective view of an example embodiment of a first device architecture 100. FIG. 1B depicts a plan view of the first device architecture 100 in the X-direction and the Y-direction. The first device architecture 100 may form a portion of a 3D memory device, as well as any other suitable three-dimensional semiconductor devices. In the example of FIG. 1A, the first device architecture 100 may take the form of a vertically stacked device, where individual device layers 103 may be stacked upon each other, and the individual device layers 103 may take the form of a memory device such as DRAM, with the resulting 3D memory device of the first device architecture 100 taking the form of a vertically stacked DRAM. However, in other embodiments, the form of the individual device layers 103 may vary, and may include one or more layers such as SRAM, SDRAM, or any other suitable memory devices, either alone or in combination. In some embodiments, at least two of the individual device layers 103 may differ from each other in terms of the number of devices, the type of devices, and the layout of the devices.

In the first device architecture 100, the addressing of individual elements such as capacitors, memory cells, or other suitable elements, may be done by use of one or more vertical electrodes 110 coupled to one or more horizontal electrodes 108 to provide signals to one or more array elements 105. In the example embodiment of FIGS. 1A-1B, the one or more vertical electrodes 110 extend substantially in the Z-direction, while the one or more horizontal electrodes 108 extend substantially in the X-direction. In some embodiments, the one or more vertical electrodes 110 may be used as the word line contact, while the one or more horizontal electrodes 108 may be used as the word line. In other embodiments, the one or more vertical electrodes 110 may be used as the bit line contact, while the one or more horizontal electrodes 108 may be used as the bit line. The one or more vertical electrodes 110 and the one or more horizontal electrodes 108 may be formed of any suitable conductive material, including metals such as tungsten or aluminum, doped semiconductor materials, functionalized carbon nanomaterials, as well as any other suitable conductive material.

The one or more vertical electrodes 110 may extend from a contact 122 on the top surface of the first device architecture 100 to a corresponding one of the one or more horizontal electrodes 108. The contact 122 may take the form of a pad suitable for forming a contact to another electrical device. At least one of the one or more vertical electrodes 110 may penetrate at least partially into at least one of the one or more horizontal electrodes 108. In some cases, the penetration may form an electrical contact between a corresponding one of the one or more horizontal electrodes 108 and the one or more vertical electrodes 110. The one or more vertical electrodes 110 may extend until reaching a dielectric supporter including a dielectric cap 106 on a dielectric pillar 109, with the dielectric cap 106 contacting the bottom of the one or more vertical electrodes 110 while the dielectric pillar 109 contacts the bottom of the dielectric cap 106. The dielectric cap 106 may extend between a first horizontal electrode 112 and at least a second horizontal electrode 114. As discussed further below, the vertical height of the dielectric cap 106 may be adjusted, such that the dielectric cap may extend to a third horizontal electrode 116 or beyond.

The dielectric pillar 109 may be made of a first dielectric, while the dielectric cap 106 may be made of a second dielectric material different from the first dielectric material, which may differ in their etch sensitivity and response to etchants. In some embodiments, the first dielectric material and the second dielectric material may include semiconductor materials, as well as nitrides, carbides, and oxides thereof. In some embodiments, the first dielectric material and the second dielectric material may consist of silicon oxide, silicon nitride, or other similar materials such as gallium nitride, gallium oxide, and so forth. In some embodiments, additional dielectric materials such as a third dielectric material or a fourth dielectric material may be used in conjunction with the first dielectric material and the third dielectric material.

An upper dielectric material 104 may extend from the one or more horizontal electrodes 108 to the upper surface of the first device architecture 100. The upper dielectric material 104 may provide spacing and isolation between the one or more vertical electrodes 110. The upper dielectric material 104 may be formed of the first dielectric material, the same as the dielectric pillar 109. An inter-electrode dielectric 111 may be formed between the one or more horizontal electrodes 108, providing isolation and separation between the one or more horizontal electrodes 108. The inter-electrode dielectric 111 may be formed of the first dielectric material, the same as the upper dielectric material 104 and the dielectric pillar 109.

The one or more vertical electrodes 110 may be formed in a pad area 120, while the one or more array elements 105 may be formed in an array area 130. Electrical signals may be provided in the pad area 120 to a contact 122, then be transmitted using one or more vertical electrodes 110 to the one or more horizontal electrodes 108 which in turn transmits the electrical signals to the one or more array elements 105 in the array area 130. On top of the one or more array elements 105 in the array area 130, one or more array dielectrics 132 may be formed. They may be formed of either the first dielectric material or the second dielectric material. The dielectric supporter, including the dielectric pillar 109 and dielectric cap 106, may be aligned in the X-direction and Y-direction with the one or more vertical electrodes 110. The dielectric cap 106 may rest directly on the dielectric pillar 109, with the one or more vertical electrodes 110 in turn resting directly on the dielectric cap 106. The dielectric cap 106 may also be aligned in the Z-direction with the bottom of the one or more horizontal electrodes 108, such that the one or more vertical electrodes 110 form a contact across the vertical extent of the one or more horizontal electrodes 108. As a result, the dielectric cap 106, the dielectric pillar 109 and the one or more vertical electrodes 110 may occupy the same location in the X and Y directions.

Additionally, the one or more vertical electrodes 110 and the one or more horizontal electrodes 108 may be in a staircase formation, where each successive contact between the one or more vertical electrodes 110 and the one or more horizontal electrodes 108 may be spaced apart both vertically and horizontally. In some embodiments, the staircase formation in conjunction with the alignment of the dielectric supporter with the one or more vertical electrodes 110 may increase the contact density of the pad area 120, as the pitch between each contact 122 is the width of the one or more vertical electrodes 110 and the spacing between each of the one or more vertical electrodes 110, without any additional spacing between each of the one or more vertical electrodes 110 and the dielectric supporters.

Between the substrate 102 and the one or more horizontal electrodes 108, a substrate isolation layer 101 may be formed. The substrate isolation layer 101 may be formed from a dielectric material, and may provide isolation between the substrate 102 and the one or more horizontal electrodes 108. In some embodiments, the substrate isolation layer 101 may be formed from the first dielectric material, the same as the dielectric pillar 109.

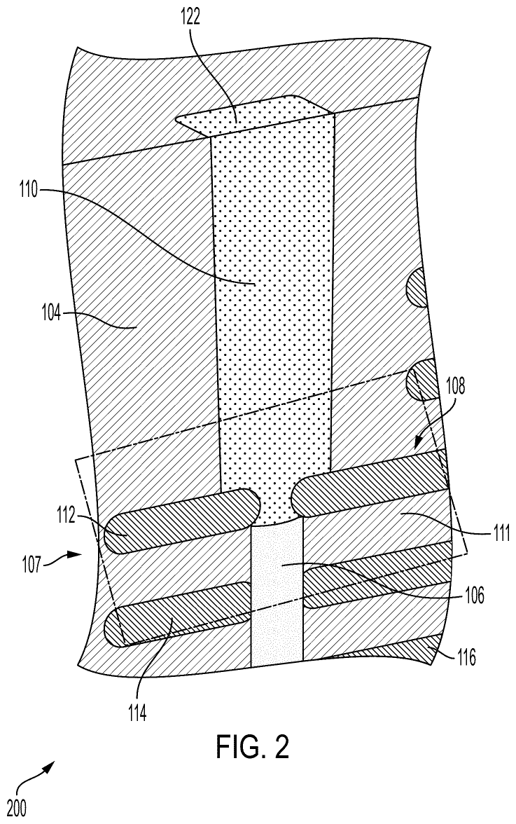

FIG. 2 provides a close-up view of a contact area 107 according to a second device architecture 200. The second device architecture 200 differs from the first device architecture 100 by having the dielectric cap 106 extend from the first horizontal electrode 112, past the second horizontal electrode 114, and to at least the third horizontal electrode 116, while the first device architecture 100 has the dielectric cap 106 extend from the first horizontal electrode 112 to the second horizontal electrode 114. As disclosed herein, the vertical height of the dielectric cap 106 may be adjusted to extend at least 1, at least 2 or at least 3 or more horizontal electrodes.

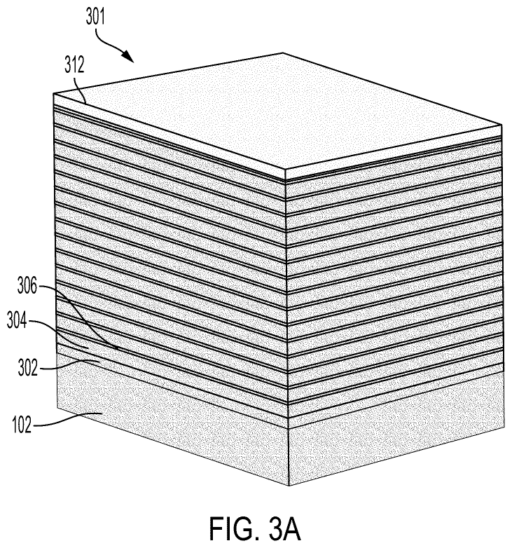

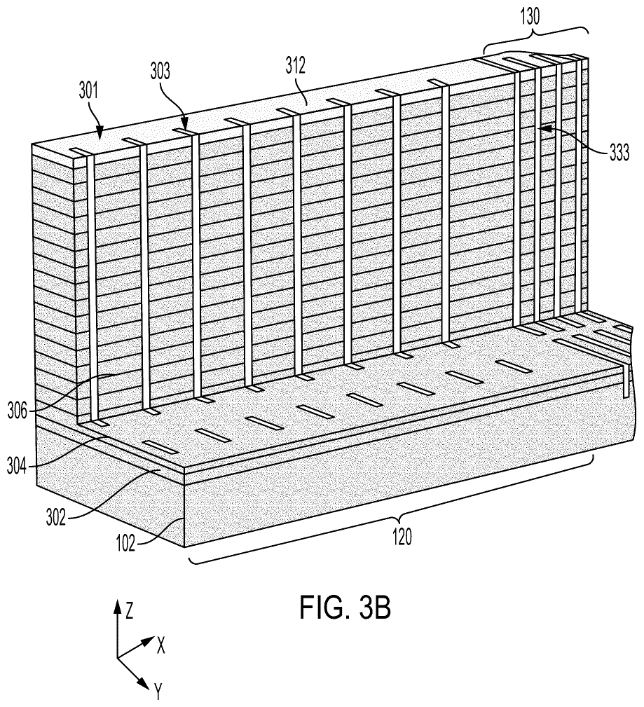

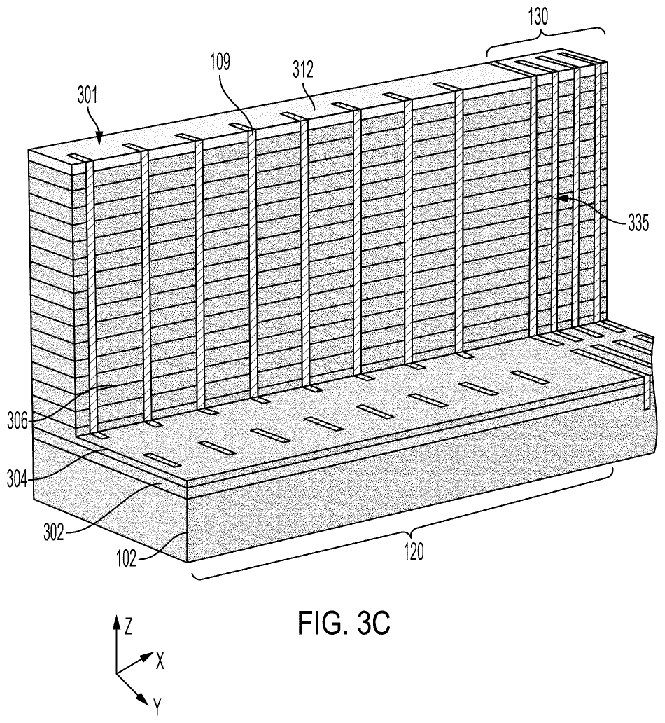

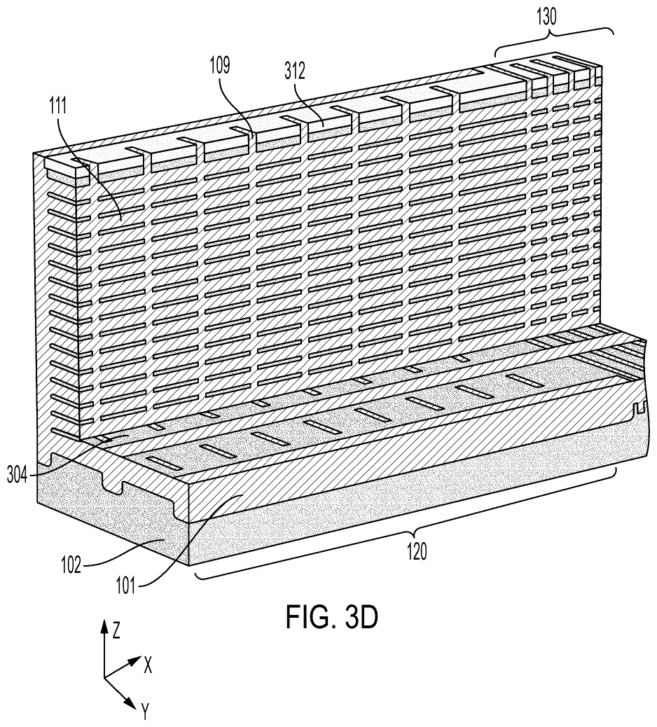

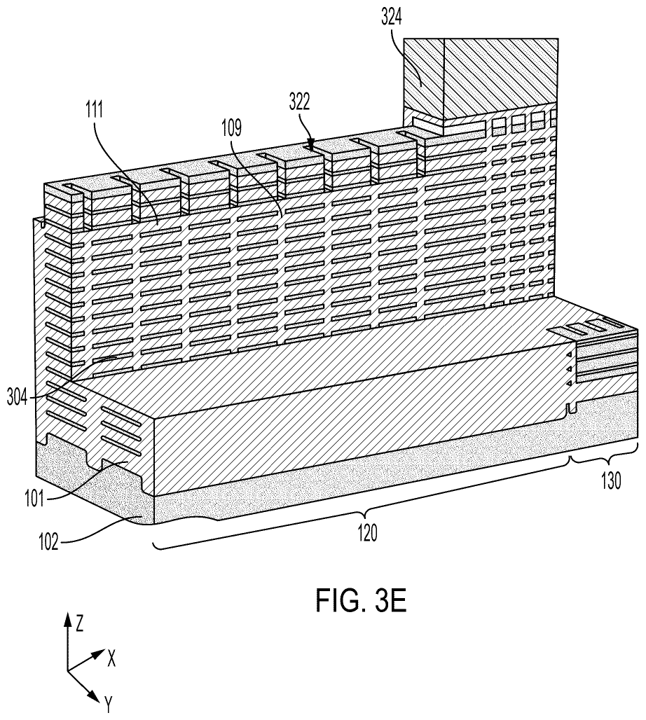

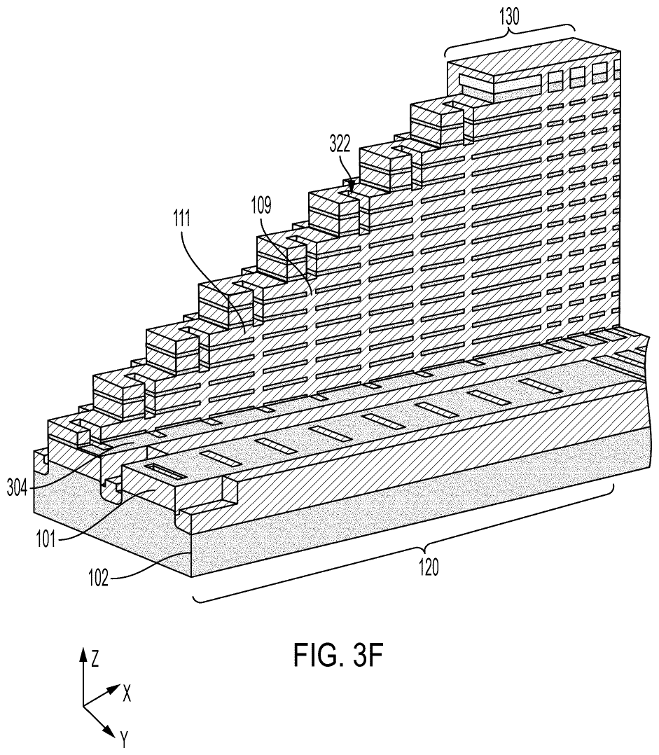

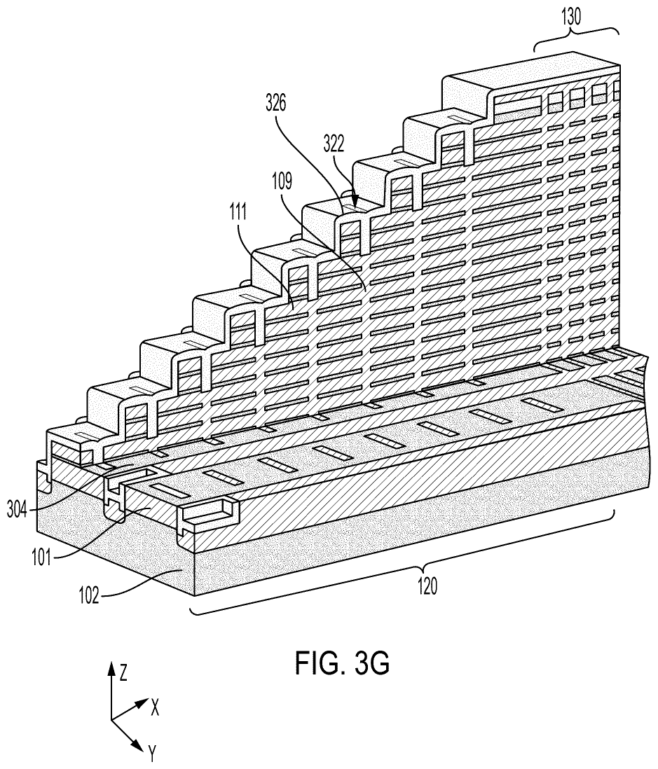

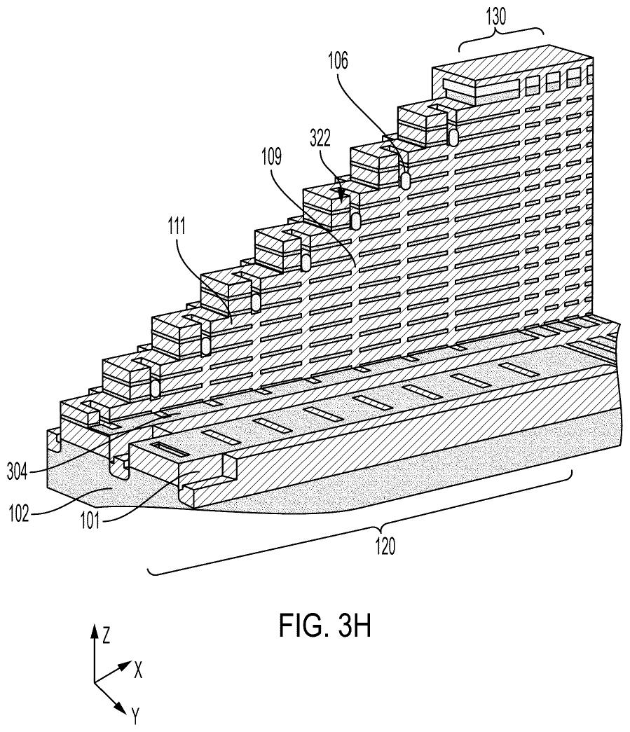

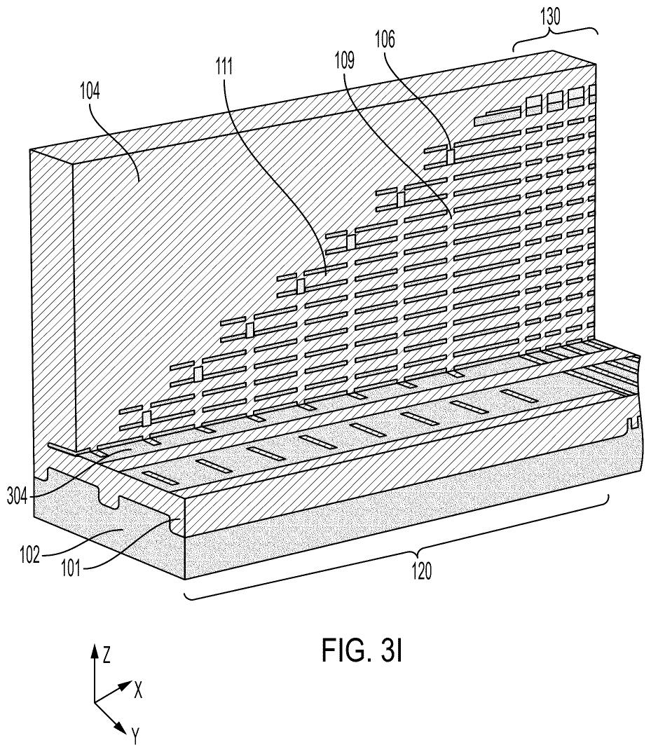

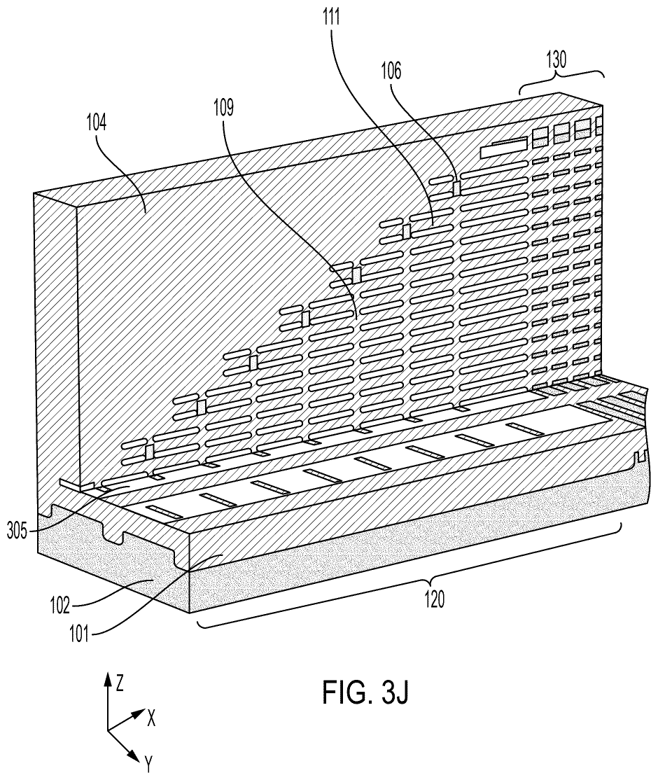

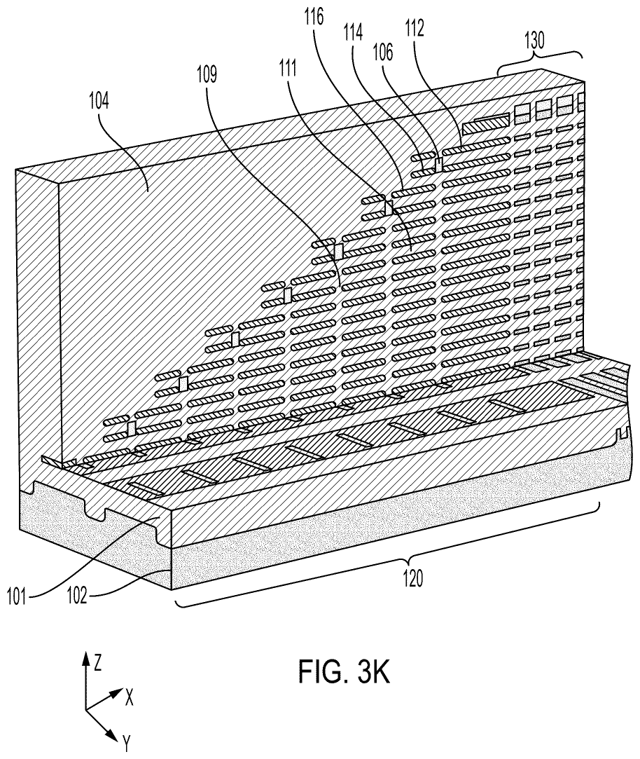

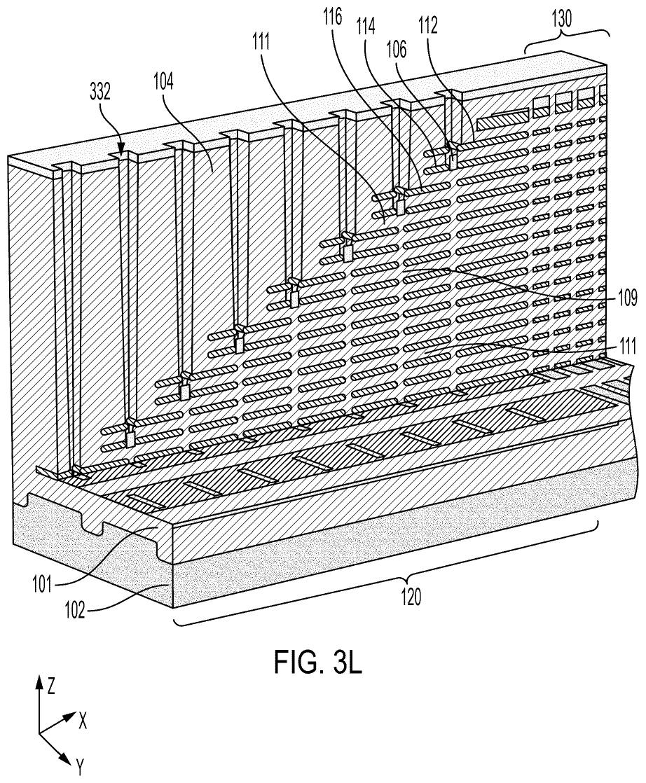

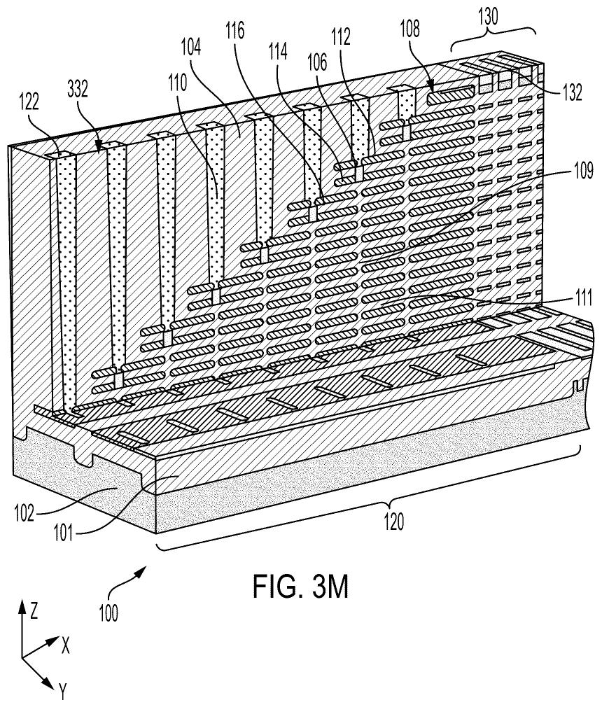

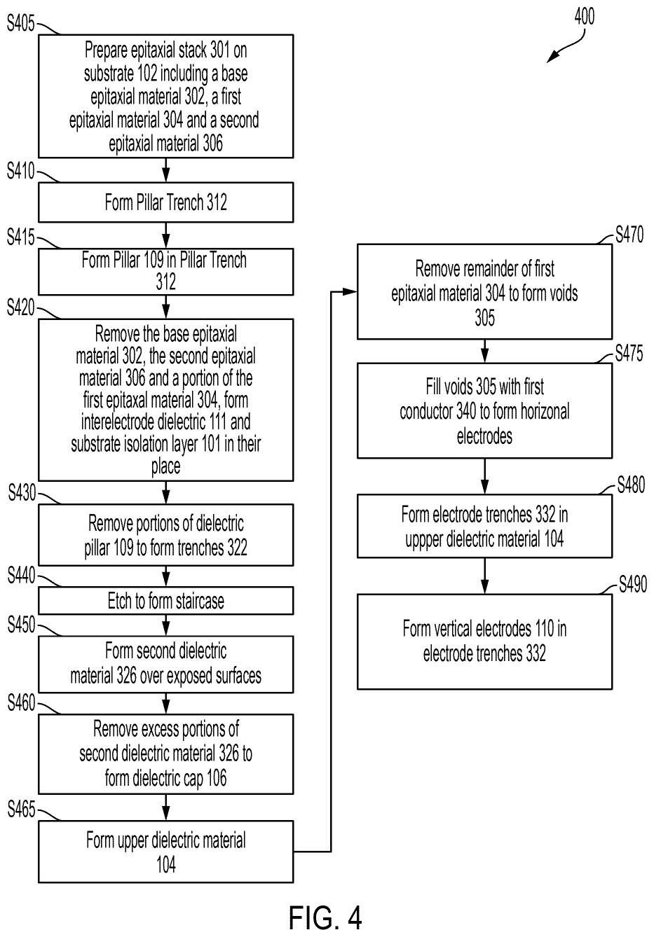

FIGS. 3A-3M depict an illustrative embodiment of a process of forming a device architecture such as the first device architecture 100, or any other device architectures shown herein in cross-sectional perspective views and perspective views of the process. FIG. 4 depicts an example embodiment of a process 400 for forming a device architecture corresponding to the illustrative embodiment of FIGS. 3A-3M.

FIG. 3A depicts S405 in the process of FIG. 4, where an epitaxial stack 301 may be prepared on substrate 102. Substrate 102 may be any suitable semiconductor substrate, such as silicon, germanium, or a combination thereof, and may take the form of a wafer, die, or a semiconductor layer formed upon an insulative substrate such as glass. The epitaxial stack 301 may have a base epitaxial layer 302 formed directly on the substrate 102 of a first epitaxial material. A first epitaxial layer 304 may be formed on top of the base epitaxial layer 302 made of a second epitaxial material, which may differ from the first epitaxial material. A second epitaxial layer 306 may in turn be formed on the first epitaxial layer 304, and the second epitaxial layer 306 may be formed of the first epitaxial material. The epitaxial stack 301 may stack alternating layers of the first epitaxial layer 304 and the second epitaxial layer 306. Finally, a capping layer 312 may be formed on top of the second epitaxial layer 306. The epitaxial layers may be formed by any suitable process, including atomic layer deposition (ALD), chemical vapor deposition (CVD), physical vapor deposition (PVD), as well as methods such as molecular beam epitaxy (MBE), alone or in combination.

The first epitaxial material of the base epitaxial layer 302 and the second epitaxial layer 306 may be formed by a mixed semiconductor, such as a combination of silicon and germanium, and may be in the range of 15-25% mol of germanium, although the concentration of germanium may be larger such as in the range of 25%-75% mol, or may be smaller such as in the range of 1%-15% mol. The second epitaxial material for the first epitaxial layer 304 may be a first single semiconductor material such as silicon or germanium, and may have a thickness of 5-15 nm, or may be larger in the range of 15-100 nm, or may be smaller in the range of 1-5 nm. The thickness of the first epitaxial layer 304 may be in the range of 5-15 nm, or may be larger in the range of 15-100 nm, or may be smaller in the range of 1-5 nm. The second epitaxial layer 306 may be formed similarly to the first epitaxial layer 304. In some embodiments, the thickness of the first epitaxial layer 304 and the second epitaxial layer 306 may be the same, while in other embodiments, the thickness may differ. The base epitaxial layer 302 may have a thickness greater than either the first epitaxial layer 304 or the second epitaxial layer 306. The base epitaxial layer 302, the first epitaxial layer 304 and the second epitaxial layer 306 may be grown epitaxially, and may have the same crystalline orientation and type as the substrate 102. Alternatively, in some embodiments, the epitaxial stack 301 may be grown on a different substrate and transferred to the substrate 102, or formed on an intermediate crystalline structure between the epitaxial stack 301 and the substrate 102, such that the epitaxial stack 301 may differ in the lattice structure and orientation from the substrate 102.

The capping layer 312 formed on the epitaxial stack 301 may, in some embodiments, be used to provide protection for the epitaxial stack 301. For example, in some embodiments, the capping layer 312 may be formed of a nitride material, such as silicon nitride, or an oxide material, such as silicon oxide. In some embodiments, the thickness of the capping layer 312 may be 10-20 nm, while in other embodiments the thickness may be smaller such as in the range of 1-10 nm, or may be larger, such as in the range of 20-100 nm or 100-1,000 nm.

FIG. 3B depicts S410 in the process of FIG. 4, where one or more pillar trenches 303 may be formed by patterning the epitaxial stack 301 in the pad area 120. The patterning may be implemented using any suitable semiconductor process, and may include techniques such as etching, including both wet-etch processes using chemicals and dry-etch processes using reactive plasma, as well as lithography, lasers, and a combination of these methods and any other suitable methods known in the art. A masking step may also be performed, such as applying a photoresist over the capping layer 312 prior to forming the one or more pillar trenches 303. The one or more pillar trenches 303 may extend from the capping layer 312 to the base epitaxial layer 302, and in some embodiments, may terminate before reaching the substrate 102. In some embodiments, the base epitaxial layer 302 may have a different thickness than the first epitaxial layer 304 or the second epitaxial layer 306 so that the base epitaxial layer 302 may form an etch stop above the substrate to provide a consistent depth for the one or more pillar trenches 303.

Additionally, one or more array trenches 333 may be formed in the array area 130 using similar processes as those used to form the one or more pillar trenches 303. However, in some embodiments, the one or more array trenches 333 may extend past the base epitaxial layer 302 and into the substrate 102.

FIG. 3C depicts S415 in the process of FIG. 4, where within the one or more pillar trenches 303 of the epitaxial stack 301, the dielectric pillar 109 may be formed. The dielectric pillar 109 may be formed using an appropriate semiconductor technique such as ALD, CVD, PVD, and may deposit a dielectric material such as a nitride, oxide, or carbide compatible with the substrate 102 and the materials of the epitaxial stack 301. Furthermore, the one or more array trenches 333 in the array area 130 may be filled with one or more array pillars 335. The one or more array pillars 335 may be formed using the same dielectric material as the dielectric pillar 109.

FIG. 3D depicts S420 in the process of FIG. 4, where the base epitaxial layer 302, the second epitaxial layer 306 and portions of the first epitaxial layer 304 are replaced with the first dielectric material to form the inter-electrode dielectric 111 and the substrate isolation layer 101. The epitaxial stack 301 may be subject to a selective removal process where the first epitaxial material of the base epitaxial layer 302 and the second epitaxial layer 306 are fully removed, while the second epitaxial material of the first epitaxial layer 304 is trimmed back. The removal process may include techniques such as etching, including both wet-etch processes using chemicals and dry-etch processes using reactive plasma, as well as lithography, lasers, and a combination of these methods and any other suitable methods known in the art. The removal process may be chosen so that the first epitaxial material is more responsive to the removal process than the second epitaxial material, such that the first epitaxial layer 304 partially remains after the base epitaxial layer 302 and the second epitaxial layer 306 are fully removed.

Within the space occupied by the removed portions of the base epitaxial layer 302, the second epitaxial layer 306 and portions of the first epitaxial layer 304 the first dielectric material may be formed to create the inter-electrode dielectric 111 and the substrate isolation layer 101. The inter-electrode dielectric 111 and the substrate isolation layer 101 may be formed of the first dielectric material. The first dielectric material may be any suitable dielectric material, including nitrides, carbides and oxides of semiconductor materials, and may consist of silicon nitride, silicon oxide, or other similar materials such as gallium nitride, gallium oxide, and so forth. The first dielectric material may be deposited using any appropriate technique, such as CVD, PVD, and ALD. In some embodiments, the inter-electrode dielectric 111 and the substrate isolation layer 101 may be separately formed, while in other embodiments the inter-electrode dielectric 111 and the substrate isolation layer 101 may be formed during the same process.

FIG. 3E depicts S430 in the process of FIG. 4, where portions of the dielectric pillar 109 are removed to form one or more trenches 322. The removal process may include techniques such as etching, including both wet-etch processes using chemicals and dry-etch processes using reactive plasma, as well as lithography, lasers, and a combination of these methods and any other suitable methods known in the art. In some embodiments, a mask such as photoresist 324 may be used to protect portions of the device from the removal process, such as the array area 130. The one or more trenches 322 may be formed such that the one or more trenches 322 extend from the surface to a selected layer of the first epitaxial layer 304. For example, the one or more trenches 322 may extend one, two, three or more of the first epitaxial layer 304 down from the surface. The depth of the one or more trenches 322 may be similar across each of the one or more trenches 322, or may differ between each of the one or more trenches 322.

The capping layer 312 may also be removed here, and capping layer 312 may be removed using a similar removal process, or during a planarization process, such as a chemical mechanical polish (CMP). In some embodiments, a selective etch may be used such that the capping layer 312 may be formed of a dielectric having a different susceptibility than the first dielectric material or the material of the first epitaxial layer 304.

FIG. 3F depicts S440 in the process of FIG. 4, where a staircase structure is formed via a selective removal process. A selective removal process may be used such that the inter-electrode dielectric 111 and the first epitaxial layer 304 are removed to form a series of steps, with the depth of the staircase extending deeper based on the distance from the array area 130. The selective removal process may include techniques such as etching, including both wet-etch processes using chemicals and dry-etch processes using reactive plasma, as well as lithography, lasers, and a combination of these methods and any other suitable methods known in the art. The process is performed evenly over each step, such that the one or more trenches 322 remain in the staircase formation, with the depth of each of the one or more trenches 322 may remain relatively consistent between S430 and S440. That is, a trench depth extending, for example, two of the first epitaxial layer 304 may be maintained after the staircase formation.

FIG. 3G depicts S450 in the process of FIG. 4, where a second dielectric material 326 is formed over the staircase formation. The second dielectric material 326 is formed from a dielectric material which may be any suitable dielectric material, including nitrides, carbides and oxides of semiconductor materials, and may consist of silicon nitride, silicon oxide, or other similar materials such as gallium nitride, gallium oxide, and so forth. The second dielectric material 326 may be deposited using any appropriate technique, such as CVD, PVD, and ALD. The second dielectric material 326 differs from the first dielectric material used to form the dielectric pillar 109, the inter-electrode dielectric 111 and the substrate isolation layer 101. The difference between the second dielectric material 326 and the first dielectric material is such that the materials differ in their susceptibility to various removal processes. For example, the first dielectric material may take the form of an oxide material such as silicon oxide, while the second dielectric material 326 may take the form of a nitride material such as silicon nitride. The difference in the dielectric materials allows the use of a removal process, such as an etch where the second dielectric material 326 may be removed while leaving the first dielectric material unaffected. The second dielectric material 326 may be formed such that the one or more trenches 322 may be filled by the second dielectric material 326. As such, the size of the one or more trenches 322 may be chosen to provide to provide a depth and width such that the process used to form the second dielectric material 326 is able to fill the trench completely.

FIG. 3H depicts S460 in the process of FIG. 4, where a selective removal process is used to remove select portions of the second dielectric material 326 to form the dielectric cap 106. The selective removal process may include techniques such as etching, including both wet-etch processes using chemicals and dry-etch processes using reactive plasma, as well as lithography, lasers, and a combination of these methods and any other suitable methods known in the art. As a result of the selective removal process, the portions of the second dielectric material 326 outside of the one or more trenches 322 may be fully removed. Addition amounts of the second dielectric material 326 may also be removed within the one or more trenches 322 with the remaining portions of the second dielectric material 326 being the dielectric cap 106. The first dielectric material within the inter-electrode dielectric 111 may be chosen such that the first dielectric material is unaffected by the process to remove the second dielectric material 326. The dielectric cap 106 may be formed such that the top surface of the dielectric cap 106 is aligned with a surface of the first epitaxial layer 304. In the example of FIG. 3H, the dielectric cap 106 has a top surface at a depth of about 1 layer of the first epitaxial layer 304 from the surface of each staircase. However, the depth of the dielectric cap 106 may vary, with the dielectric cap 106 able to be placed 2, 3 or more layers of the first epitaxial layer 304 in depth. Furthermore, the depth of the top surface of the dielectric cap 106 may also vary, with the depth of the top surface of the dielectric cap 106 being able to be placed 2, 3 or more layers of the first epitaxial layer 304 down from the surface.

FIG. 3I depicts S465 in the process of FIG. 4, where the upper dielectric material 104 is formed over the staircase formation as well as the dielectric cap 106, and fills the one or more trenches 322. The upper dielectric material 104 may be formed of the first dielectric material, and may be formed of any suitable dielectric material, including nitrides, carbides and oxides of semiconductor materials, and may consist of silicon nitride, silicon oxide, or other similar materials such as gallium nitride, gallium oxide, and so forth. The upper dielectric material 104 may be deposited using any appropriate technique, such as CVD, PVD, and ALD. The upper dielectric material 104 may be formed such that the top surface of the pad area 120 and the array area 130 is planar. In some embodiments, a planarization process such as CMP may be used to create a planar surface.

FIG. 3J depicts S470 in the process of FIG. 4, where the remaining portions of the first epitaxial layer 304 within the pad area 120 are removed. The removal may be performed using a selective removal process, which may include techniques such as etching, including both wet-etch processes using chemicals and dry-etch processes using reactive plasma, as well as lithography, lasers, and a combination of these methods and any other suitable methods known in the art. As a result of the selective removal process, a series of voids 305 may be formed in the pad area 120. In some embodiments, the first dielectric material may be partially trimmed back by the selective removal process, while in other embodiments, only the first epitaxial layer 304 may be affected.

FIG. 3K depicts S475 in the process of FIG. 4, where the one or more horizontal electrodes 108 are formed in the voids 305. The one or more horizontal electrodes 108 may be formed of a suitable conductive material, including metals such as tungsten or aluminum, doped semiconductor materials, functionalized carbon nanomaterials, as well as any other suitable conductive material. The one or more horizontal electrodes 108 may be deposited using any appropriate technique, such as CVD, PVD, and ALD, either alone or in combination.

FIG. 3L depicts S480 in the process of FIG. 4, where electrode trenches 332 are formed in the upper dielectric material 104. The electrode trenches 332 are formed using a selective removal process, which may include techniques such as etching, including both wet-etch processes using chemicals and dry-etch processes using reactive plasma, as well as lithography, lasers, and a combination of these methods and any other suitable methods known in the art. The selective removal process may be such that the first dielectric material used to form the upper dielectric material 104 may be removed, while the second dielectric material in the dielectric cap 106 may be unaffected. As such, the dielectric cap 106 may form an etch stop. The top surface of the dielectric cap 106 may thus be aligned with one of the one or more horizontal electrodes 108, in order to provide a suitable space for forming an electrode.

FIG. 3M depicts S490 in the process of FIG. 4, where a conductor is formed within the electrode trenches 332 to form the one or more vertical electrodes 110. The one or more vertical electrodes 110 may be formed of a suitable conductive material, including metals such as tungsten or aluminum, doped semiconductor materials, functionalized carbon nanomaterials, as well as any other suitable conductive material. The one or more vertical electrodes 110 may be deposited using any appropriate technique, such as CVD, PVD, and ALD, either alone or in combination. In some embodiments, masking, patterning, or planarization processes may be used in combination with deposition processes to remove any excess conductive material. The one or more vertical electrodes 110 may extend from the contact 122 formed on the top surface of the device to a corresponding one of the one or more horizontal electrodes 108. The one or more vertical electrodes 110 may thus rest on the top surface of the dielectric cap 106, which in turn is supported by the dielectric pillar 109.

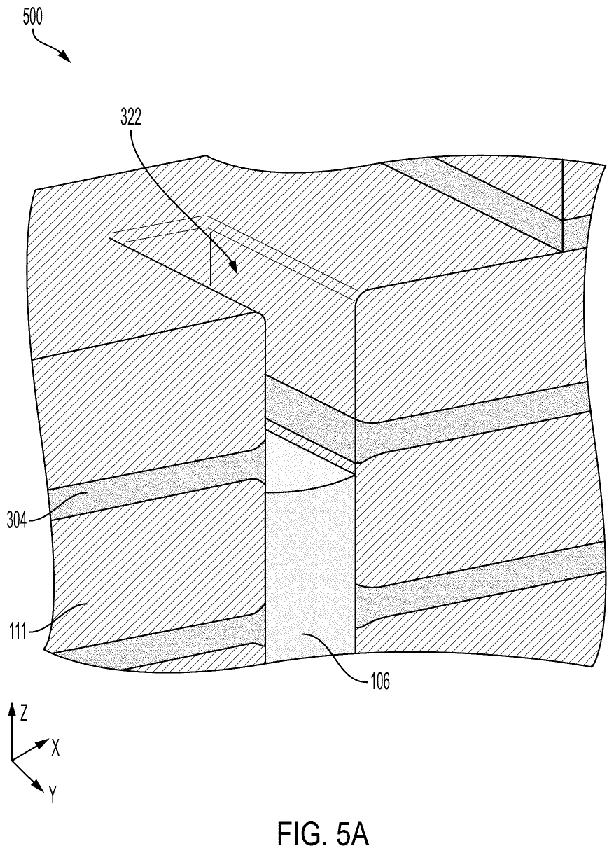

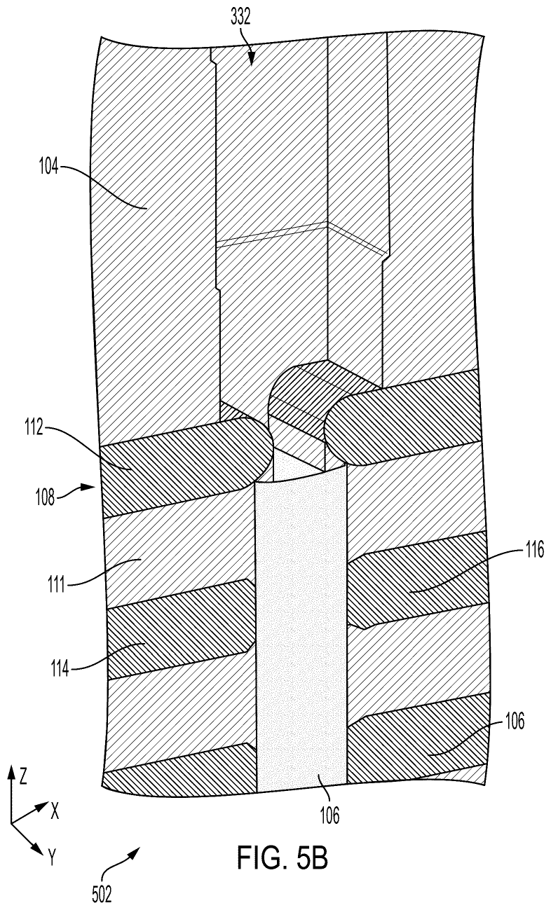

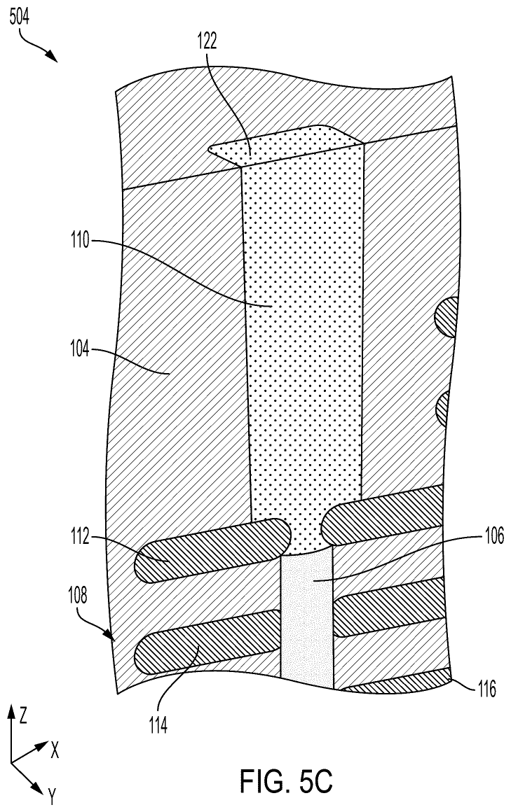

FIGS. 5A-5C depict various alternatives of the formation of the contact area 107 for the second device architecture 200. FIG. 5A depicts a close up view 500 of the contact area 107 at S460 for the second device architecture 200. In the second device architecture 200, the dielectric cap 106 may extend within the trenches 322 beyond the first horizontal electrode 112 and the second horizontal electrode 114 to the third horizontal electrode 116. As such, at S460 the dielectric cap may extend beyond a first of the first epitaxial layer 304 and beyond a second of the first epitaxial layer 304, and may extend to a third of the first epitaxial layer 304 or beyond. In addition, the dielectric cap 106 may be recessed slightly from a top-most of the first epitaxial layer 304.

FIG. 5B depicts a close up view 502 of the contact area 107 at S480 for the second device architecture 200. In FIG. 5B, the first epitaxial layer 304 has been removed to form the one or more horizontal electrodes 108, and the electrode trenches 332 have been formed to extend down to the first horizontal electrode 112. As the second dielectric material used to form the dielectric cap 106 differs from the first dielectric material used to form the upper dielectric material 104, differences in response to different removal processes such as etchants allows the dielectric cap 106 to function as an etch stop. In addition, the conductor used to form the one or more horizontal electrodes 108 may also differ in response to different removal processes, such that portions of the one or more horizontal electrodes 108 which are exposed during the formation of the trenches 322 may act as an additional etch stop. As such, the trenches 322 have a margin of error, which simplifies the formation of the one or more vertical electrodes 110.

FIG. 5C depicts a close up view 504 of the contact area 107 at S490 for the second device architecture 200. The one or more vertical electrodes 110 are formed by depositing conductor within the trenches 322. The conductor may fill in the exposed spaces, extending around exposed portions of the dielectric cap 106 and the one or more horizontal electrodes 108.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific example teachings discussed above, but is instead defined by the following claims.

What is claimed is:

1. A device comprising:
a substrate having a planar surface;
a first electrode extending in a first direction orthogonal to the planar surface of the substrate;
a second electrode extending in a second direction parallel to the planar surface of the substrate, the second electrode contacting the first electrode;
a third electrode extending in the second direction;
a first dielectric material arranged between the first electrode and the third electrode, the first dielectric material contacting the first electrode; and
a second dielectric material arranged between the first electrode and the second electrode,
wherein the first dielectric material is arranged between the first electrode and the second dielectric material.

2. The device of claim 1, wherein:
the first dielectric material comprises at least one of carbide, nitride or oxide, and
the second dielectric material comprises at least one of carbide, nitride or oxide.

3. The device of claim 1, wherein the first dielectric material differs from the second dielectric material.

4. The device of claim 1, wherein:
the first electrode extends from a contact on a surface of the device to the second electrode; and
the third electrode is electrically isolated from the first electrode.

5. The device of claim 1, wherein:
the first dielectric material extends in the first direction; and
the second dielectric material extends in the second direction.

6. The device of claim 1, further comprising:
a fourth electrode, the fourth electrode extending in the first direction, the fourth electrode contacting the third electrode,
wherein the fourth electrode is electrically isolated from the first electrode.

7. The device of claim 1, wherein the second electrode is a word line.

8. A system comprising:
a substrate having a planar surface;
a first electrode extending in a first direction orthogonal to the planar surface of the substrate, the first electrode extending from a first contact to a second electrode, the second electrode extending in a second direction parallel to the planar surface of the substrate;
a third electrode extending in the first direction, the third electrode extending from a second contact to a fourth electrode, the fourth electrode extending in the second direction;
a first dielectric material arranged between the first electrode and the third electrode; and
a second dielectric material arranged between the second electrode and the fourth electrode,
wherein the second dielectric material is arranged between the first dielectric material and the first electrode.

9. The system of claim 8, wherein the first dielectric material comprises at least one of carbide, nitride or oxide, and wherein the second dielectric material comprises at least one of carbide, nitride or oxide.

10. The system of claim 8, wherein the first dielectric material extends in the first direction.

11. The system of claim 8, wherein the first electrode is electrically isolated from the fourth electrode.

12. The system of claim 8, wherein the material of the first dielectric material is different from a material of the second dielectric material.

13. The system of claim 8, wherein the second dielectric material extends in the second direction beyond the fourth electrode.

14. A method comprising:
forming a dielectric pillar on a substrate, the substrate having a planar surface;
forming a first trench within the dielectric pillar;
forming a dielectric cap within the first trench, the dielectric cap aligned with a first electrode, the first electrode extending in a first direction parallel to the planar surface of the substrate;
forming an upper dielectric material over the dielectric cap;
removing at least a portion of the upper dielectric material to form a second trench; and
forming a conductor within the second trench extending from the first electrode to a surface contact, the conductor forming a second electrode, the second electrode extending in a second direction orthogonal to the planar surface of the substrate,
wherein the dielectric pillar and the upper dielectric material are formed of a first dielectric material, and wherein the dielectric cap is formed of a second dielectric material, the second dielectric material different from the first dielectric material.

15. The method of claim 14, wherein forming the conductor is based on at least one of chemical vapor deposition, physical vapor deposition, or atomic layer deposition.

16. The method of claim 14, wherein:
the first dielectric material comprises an oxide, and
the second dielectric material comprises a nitride.

17. The method of claim 14, wherein forming the first dielectric material is performed by at least one of atomic layer deposition and chemical vapor deposition.

18. The method of claim 14, wherein the second dielectric material acts as an etch stop during formation of the second trench.

19. The method of claim 14, further comprising, prior to forming the dielectric cap within the first trench, forming a staircase formation, the staircase formation including a first trench at a first depth and a second trench at a second depth greater than the first trench.

20. The method of claim 14, wherein dielectric cap is arranged between the second electrode and the dielectric pillar.
